(19) United States
(12) Patent Application Publication
(10) Pub. No.: US 2025/0294832 A1
(43) Pub. Date: Sep. 18, 2025

(54) CONTACT FORMATION FOR BACK SIDE POWER DISTRIBUTION

(71) Applicant: Applied Materials, Inc., Santa Clara, CA (US)

(72) Inventors: Shi YOU, San Jose, CA (US); He REN, Santa Clara, CA (US); Mehul Bhagubhai NAIK, San Jose, CA (US); Johannes M. VAN MEER, Middleton, MA (US); Jae Young LEE, Bedford, MA (US); Naushad K. VARIAM, Marblehead, MA (US); Shashank SHARMA, Santa Clara, CA (US)

(73) Assignee: Applied Materials, Inc., Santa Clara, CA (US)

(21) Appl. No.: 18/602,916

(22) Filed: Mar. 12, 2024

(51) Int. Cl. H01L 29/08; H01L 21/265; H01L 21/285

(52) U.S. Cl. CPC H10D 62/151; H01L 21/26513; H01L 21/28518

(57) ABSTRACT

Approaches of the disclosure provide contact formation for back side power distribution. One method may include forming a source/drain (S/D) epitaxial region in a front side of a substrate, and forming a back side epitaxial layer atop the S/D epitaxial region, wherein the back side epitaxial layer is formed within a contact via of a back side of the substrate. The method may further include amorphizing the back side epitaxial layer by delivering a pre-amorphization implant into the contact via, and implanting a dopant into the back side epitaxial layer after the back side epitaxial layer is amorphized. The method may further include performing a thermal treatment to the back side epitaxial layer following the dopant implant, wherein the thermal treatment is performed at a temperature less than 650° C.

### FIELD OF THE DISCLOSURE

The present disclosure generally relates to the field of semiconductor devices and methods for manufacturing semiconductor devices. More particularly, the disclosure relates to methods of contact formation for back side power distribution.

### BACKGROUND OF THE DISCLOSURE

Transistors used in logic and memory require a power source to operate. The power is typically supplied by a power rail which connects each transistor to the power source. Architectures that include a front side power grid have the power rail intermixed with signal lines used by the transistors, creating a network of interleaved power rails and signal lines. Traditional back side power sources may utilize vias that extend into the transistors. Similarly, buried power rails that connect to the transistors also increase the area used by the transistors.

Current approaches for forming contacts require a high temperature anneal (e.g., greater than 850° C.) to a front side to achieve adequate dopant activation with low contact resistance. However, this high temperature anneal exceeds the thermal budget required for back side power distribution applications.

Accordingly, an improved approach is needed for contact formation with lower contact resistance and adequate dopant activation, but with reduced processing temperatures.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a source/drain (S/D) epitaxial region in a front side of a substrate, and forming a back side epitaxial layer atop the S/D epitaxial region, wherein the back side epitaxial layer is formed within a contact via of a back side of the substrate. The method may further include amorphizing the back side epitaxial layer by delivering a pre-amorphization implant into the contact via, and implanting a dopant into the back side epitaxial layer after the back side epitaxial layer is amorphized. The method may further include performing a thermal treatment to the back side epitaxial layer following the dopant implant, wherein the thermal treatment is performed at a temperature less than 650° C.

In another aspect, a method of forming a back side contact may include forming a S/D epitaxial region in a front side of a substrate, and forming a back side epitaxial layer atop the S/D epitaxial region, wherein the back side epitaxial layer is formed within a contact via of a back side of the substrate. The method may further include amorphizing the back side epitaxial layer by delivering a pre-amorphization implant into a top surface of the back side epitaxial layer, and implanting a dopant into the back side epitaxial layer after the back side epitaxial layer is amorphized. The method may further include performing a thermal treatment to the back side epitaxial layer following the dopant implant, wherein the thermal treatment is performed at a temperature less than 650° C., and forming a back side contact within the contact via by siliciding the back side epitaxial layer and forming a metal fill within the contact via.

In yet another aspect, a method of forming a back side contact of a metal oxide semiconductor may include forming a S/D epitaxial region in a front side of a substrate, and forming a back side epitaxial layer atop the S/D epitaxial region, wherein the back side epitaxial layer is formed within a contact via of a back side of the substrate. The method may further include amorphizing the back side epitaxial layer by delivering a pre-amorphization implant into a top surface of the back side epitaxial layer, wherein the pre-amorphization implant is performed at a temperature less than 0° C., and implanting a dopant into the back side epitaxial layer after the back side epitaxial layer is amorphized. The method may further include performing a thermal treatment to the back side epitaxial layer following the dopant implant, wherein the thermal treatment is performed at a temperature less than 650° C., and forming a back side contact within the contact via.

### BRIEF DESCRIPTION OF THE DRAWINGS

The accompanying drawings illustrate approaches of the disclosure, including the practical application of the principles thereof, as follows:

FIG. 1 illustrates a side view of a portion of a semiconductor device including a source/drain epitaxial region formed in a substrate, according to implementations of the present disclosure;

FIG. 2 illustrates a side view of the semiconductor device during a pre-amorphization implant, according to implementations of the present disclosure;

FIG. 3 illustrates a side view of the semiconductor device during a dopant implant, according to implementations of the present disclosure;

FIG. 4 illustrates a side view of the semiconductor device during a thermal treatment, according to implementations of the present disclosure;

FIG. 5 illustrates a side view of the semiconductor device during formation of metal silicide layer, according to implementations of the present disclosure;

FIG. 6 illustrates a side view of the semiconductor device during formation of metal fill, according to implementations of the present disclosure; and

FIG. 7 illustrates a perspective view of an example processing system, according to implementations of the present disclosure.

The drawings are not necessarily to scale. The drawings are merely representations, not intended to portray specific parameters of the disclosure. The drawings are intended to depict exemplary implementations of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various implementations are shown. The methods, systems, and devices may be embodied in many different forms and are not to be construed as being limited to the implementations set forth herein. Instead, these implementations are provided so the disclosure will be thorough and complete, and will fully convey the scope of the methods to those skilled in the art.

Implementations of the present disclosure relate to back side contact formation with low contact resistivity for back side power distribution applications. Using a pre-amorphization implant, a dopant implant, and a low temperature (e.g., less than approximately 650° C.) anneal, a high dopant activation may be achieved at a relatively lower temperature to prevent damage to back side components.

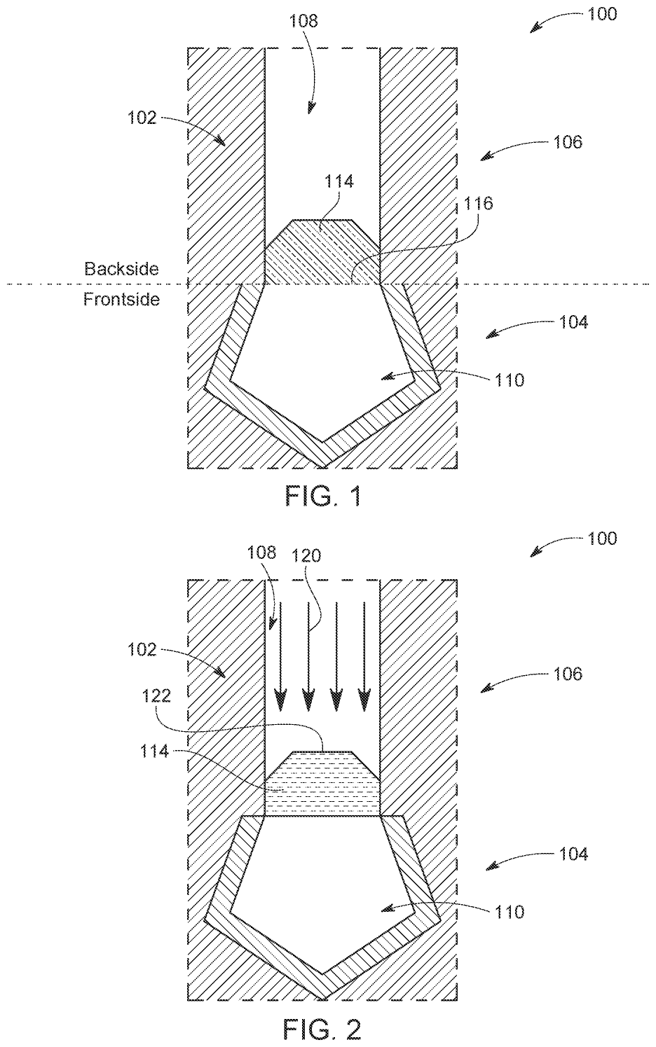

With reference to FIG. 1, an approach for forming a portion of a device 100, which may be a semiconductor device, according to one or more implementations will be described. In some implementations, the device 100 may be a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, memory devices, other suitable components, or combinations thereof.

The device 100 may include a layer or substrate 102 having a front side 104 opposite a back side 106. The substrate 102 may be or include a bulk semiconductor substrate, a semiconductor-on-insulator (SOI) substrate, or the like, which may be doped (e.g., with a p-type dopant or an n-type dopant) or undoped. In some implementations, the semiconductor material of the substrate 102 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GalnAs, GalnP, and/or GaInAsP; a combination thereof, or the like. The substrate 102 may further include additional materials, for example, silicide layers, metal silicide layers, metal layers, dielectric layers, etch stop layers, interlayer dielectrics, or a combination thereof.

As further shown, the device 100 may include a trench or contact via 108 in the back side 106 of the substrate 102 and a source/drain epitaxial region (S/D epi) 110 in the front side 104 of the substrate 102. The S/D epi 110 may be formed from epitaxially grown semiconductor material, which may be or include silicon, silicon germanium, silicon carbide, silicon phosphorous, silicon carbon phosphorous, pure or substantially pure germanium, a III-V compound semiconductor, a II-VI compound semiconductor, or the like. The semiconductor material may be doped, for example, doped with an n-type dopant. The S/D epi 110 may be doped by in-situ doping during epitaxial growth or by implanting dopants into the S/D epi 110 after epitaxial growth. In some implementations, the S/D epi 110 may be formed from phosphorous-doped silicon or p-doped silicon (Si: P).

As further shown, a back side epitaxial layer (hereinafter “back side epi”) 114 may be formed atop the S/D epi 110, within the contact via 108. In some implementations, the back side epi 114 may be a doped crystalline silicon-containing layer, which is epitaxially grown directly atop an upper surface 116 of the S/D epi 110. In some implementations, the epitaxial growth process is performed at lower temperatures, for example, a temperature of 500 degrees Celsius or less, 480 degrees Celsius or less, 450 degrees Celsius or less, 400 degrees Celsius or less, 350 degrees Celsius or less, and so on. During the epitaxial growth process, positioning the substrate 102 in a processing region of a processing chamber may include adjusting one or more processing conditions, such as temperature, pressure, and/or carrier gas (e.g., Ar, N2, H2, or He) flow rate, to conditions suitable for epitaxial film formation.

In some implementations, the back side epi 114 is a silicon germanium (SiGe) layer, and the deposition gas includes a germanium source. Suitable germanium sources include germane (GeH4) and higher order germanes. Higher order germanes include compounds with the empirical formula GexH (2x+2), where x is two or more, for example, where x is two, three, four, or more. Examples of higher order germanes include digermane (Ge2H6), trigermane (Ge3H8) and tetragermane (Ge4H10), as well as others.

Although not shown, a pre-clean process may be performed in some implementations prior to formation of the back side epi 114. The pre-clean process can include one more dry clean processes, which may include a plasma etch process, such as a two-part dry chemical clean process using NF3 and NH3, an H2 and O2 plasma etch process, an H2 plasma etch process, an NF3/H2 plasma etch, a remote plasma etch including one or more of H2, H2O, NH3, and argon, or a combination thereof. The dry clean process may be used to remove oxides from the exposed surfaces of the device 100, including the upper surface 116 of the S/D epi 110. For example, if the semiconductor device 100 includes silicon, a SICONI® clean process, available from Applied Materials, Inc., located in Santa Clara, California, may be performed for removing oxides from the exposed surfaces of the S/D epi 110. The SICONI® clean process removes native oxides through a low-temperature, two-part dry chemical clean process using NF3 and NH3. The clean process may be performed in a processing chamber positioned on a cluster tool.

As shown in FIG. 2, the back side epi 114 may then be amorphized by delivering a pre-amorphization implant (PAI) 120 into an upper surface 122 of the back side epi 114, through the contact via 108. In some implementations, the PAI 120 includes delivering germanium ions or gallium ions into the back side epi 114 while the device 100 is maintained at a cryogenic temperature, e.g., less than 0° C. For example, one or more ion implants may be performed between 0 and −100 degrees Celsius (C) to amorphize SiGe to suppress implant channeling. In some implementations, the cryogenic ion implant includes chilling a platen (not shown) upon which the device 100 is provided.

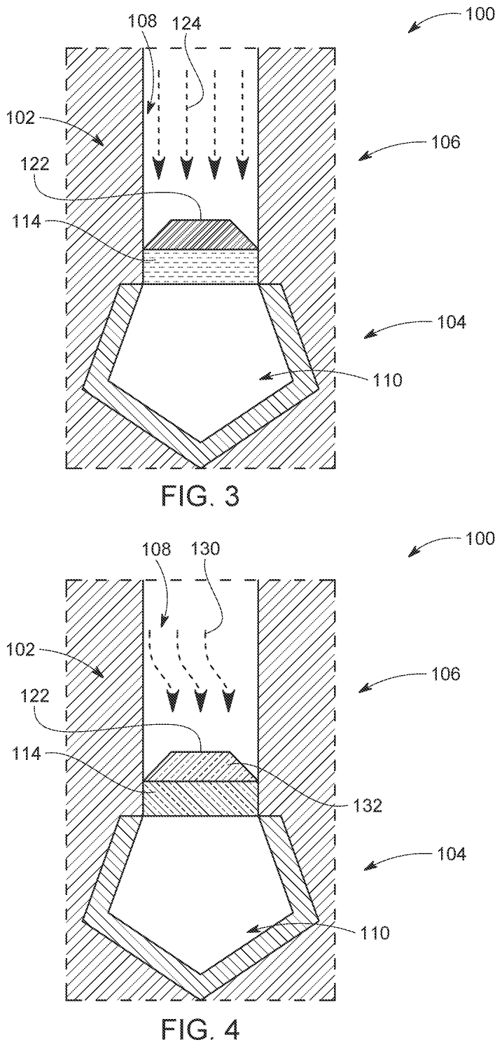

As shown in FIG. 3, a dopant implant 124 may then be performed to deliver ions into the back side epi 114 after the back side epi 114 has been amorphized as a result of the PAI 120. In some implementations, the dopant implant 124 includes delivering PMOS dopants, such as boron or gallium, into the upper surface 122 of the back side epi 114. The dopant implant 124 may be performed at a pre-defined angle, energy, dose, temperature, etc.

As shown in FIG. 4, a thermal treatment process 130 may then be performed on the device 100. In some implementations, the thermal treatment process 130 may include a millisecond laser anneal operable to form an area of regrowth 132 along the upper surface 122 of the back side epi 114. The thermal treatment process 130 may also activate the dopants of the back side epi 114. In some implementations, the device 100, and therefore the back side epi 114, is subjected to a “short-term” thermal anneal performed at a temperature less than 650° C. More specifically, the thermal treatment process 430 may heat the upper surface 122 to be approximately 650° C., which is in equivalent to approximately 400° C. Si bulk temperature. As used herein, short-term thermal anneal may refer to a process where the upper surface 122 of the back side epi 114 is heated to a desired temperature for a period of about 100 milliseconds or less and, preferably, for a period of about 10 milliseconds or less.

In one non-limiting implementation, the short-term thermal anneal includes laser annealing by a dynamic/direct surface annealing (DSA) process, which can be conducted on a DSA platform, available from Applied Materials, Inc., located Santa Clara, California. Generally, the laser emits light with a wavelength selected from 10.6 μm or 0.81 μm. In another implementation, the short-term thermal anneal may be a flash RTP process. As a result of the short-term thermal anneal, the area of regrowth 132 may have a thickness (e.g., in the vertical direction) of approximately 3-10 nm, while a dopant concentration density of the back side epi 114 may be greater than 1E21 at/cc.

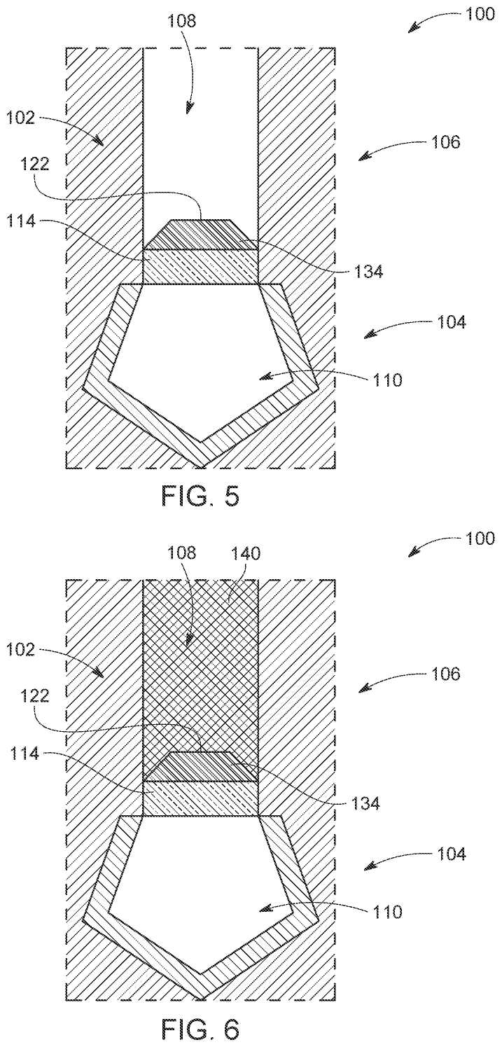

As shown in FIG. 5, a silicide layer 134 may then be formed along the upper surface 122 of the back side epi 114, within the contact via 108, following the thermal treatment process 130. In some implementations, the silicide layer 134 may be a molybdenum silicide (MoSiₓ) layer deposited over the back side epi 114 by any suitable means (e.g., a chemical vapor deposition (CVD) process). For example, the substrate 102 may be exposed to a process gas for a period of time, wherein the process gas includes a molybdenum precursor, which reacts with the surface of the back side epi 114 to deposit a molybdenum film. The reactive gas may also be referred to as the metal precursor gas.

The molybdenum precursor may be any suitable precursor to react with the back side epi 114. In some implementations, the molybdenum precursor comprises a metal center and one or more ligands. In some implementations, the metal center comprises one or more metal atoms. Stated differently, in some implementations, the metal precursor is one or more of a dimer, trimer, or tetramer. The molybdenum precursor can be any suitable precursor with a decomposition temperature above the deposition temperature. The molybdenum precursors of one or more implementations are volatile and thermally stable, and, thus, suitable for vapor deposition. Implementations herein are not limited in this context, however.

In one or more non-limiting implementations, the deposition process is cyclic; per cycle, the exposure time per cycle of the molybdenum precursor is about 500 msec. Then the flow is turned off for about 3.5 sec. The temperature of the substrate during exposure to the molybdenum precursor can be controlled, for example, by setting the temperature of the substrate support or susceptor. In some implementations the substrate 102 is held at a temperature in the range of about 0° C. to about 600° C., or in the range of about 25° C. to about 500° C., or in the range of about 50° C. to about 450° C., or in the range of about 100° C. to about 400° C., or in the range of about 200° C. to about 400° C., or in the range of about 250° C. to about 350° C. In some implementations, the substrate 102 is maintained at a temperature below the decomposition temperature of the metal precursor. In some implementations, optionally, the silicide layer 134 may then be annealed.

As shown in FIG. 6, a conductive metal fill 140 may be provided within the contact via 108 to form a contact atop the silicide layer 134 and back side epi 114. In one or more implementations, the conductive metal fill 140 may be deposited after a sacrificial gap fill material has been removed. In some implementations, the conductive metal fill 140 may include any conductive material such as copper (Cu), ruthenium (Ru), tungsten (W), cobalt (Co), titanium (Ti), molybdenum (Mo), or any alloys thereof. In some implementations, the contact includes the conductive metal fill 140 together with one or more layers of different conductive materials, such as the silicide layer 134.

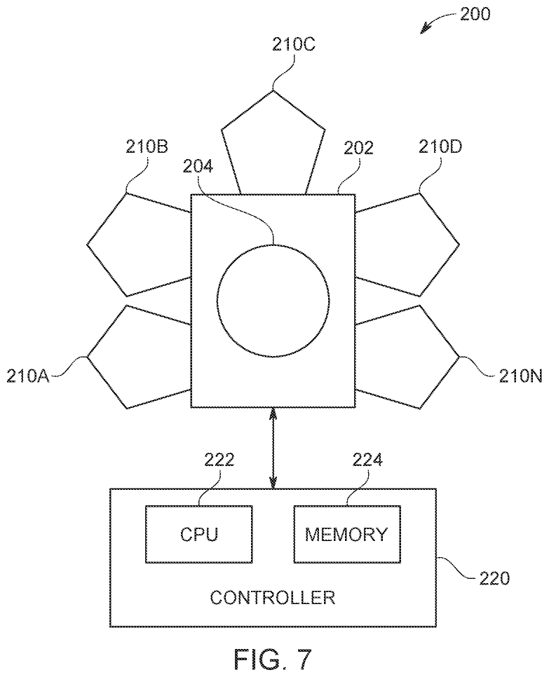

FIG. 7 shows a schematic of an example apparatus/system 200 according to implementations of the disclosure. In some implementations, the system 200 may be a cluster tool operable to perform processes necessary to form the device 100 described herein. Examples of processing systems that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

As shown, the system 200 may include at least one central transfer station/chamber 202 and one or more robots 204 within the transfer station/chamber 202, wherein the robot 204 is operable to move a robot blade and a wafer to and from each of a plurality of processing chambers 210A-210N connected with, or positioned adjacent to, the transfer station/chamber 202. In some implementations, the processing chambers 210A-210N may support ion implantation, material deposition, material etching, thermal processing, and others. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some implementations, processing chamber 210A may be a deposition chamber operable to deposit one or more layers of the device 100. For example, the processing chamber 210A may include a material deposition tool operable to form the S/D epi 110 within the front side 104 of the substrate 102, and to form the back side epi 114 atop the S/D epi 110. The material deposition tool may be further operable to form the metal fill 140 within the contact via 108 to form the contact. Although non-limiting, the deposition chamber may include one or more of an atomic layer deposition chamber, a plasma enhanced atomic layer deposition chamber, a chemical vapor deposition chamber, a plasma enhanced chemical vapor deposition chamber, or a physical deposition. The deposition chamber may further be an epitaxial growth deposition chamber.

In some implementations, processing chamber 210B may be an etch chamber operable to form one or more trenches through the body of the device 100. For example, the processing chamber 210B may include an ion etching tool operable to form the contact via 108 in the substrate 102. In some implementations, processing chamber 210B may be used for wet and/or dry etch processes. In some implementations, the processing chamber 210B may be further operable to planarize the device 100, e.g., to partially remove the metal fill 140 within the contact via 108.

In some implementations, processing chamber 210C may be operable to perform an ion implant to the device 100. For example, the processing chamber 210C may include an ion implanter operable to amorphize the back side epi 114 by delivering the pre-amorphization implant 120 into the contact via 108. In some implementations, the pre-amorphization implant 120 is performed at a cryogenic temperature, e.g., between −100° C. and 0° C. The ion implanter may be further operable to deliver the dopant implant 124 into the back side epi 114 after the back side epi 114 is amorphized. In some implementations, the dopant may be a PMOS dopant (e.g., B or Ga), which is delivered into the top surface 122 of the of the back side epi 114. Although non-limiting, the pre-amorphization implant 120 and the dopant implant 124 may include one or more beamline implants delivered at a pre-defined angle, a predefined energy, a predefined dose, etc.

In some implementations, processing chamber 210D may be operable to perform one or more thermal processes. For example, the processing chamber 210D may be used to perform the millisecond laser anneal to the back side epi 114 at a temperature less than 650° C.

A system controller 220 is in communication with the robot 204, the transfer station/chamber 202, and the plurality of processing chambers 210A-210N. The system controller 220 can be any suitable component that can control the processing chambers 210A-210N and robot(s) 204, as well as the processes occurring within the process chambers 210A-210N. For example, the system controller 220 can be a computer including a central processor 222, memory 224, suitable circuits/logic/instructions, and storage.

Processes or instructions may generally be stored in the memory 224 of the system controller 220 as a software routine that, when executed by the processor 222, causes the processing chambers 210A-210N to perform processes of the present disclosure. The software routine may also be stored and/or executed by a second processor (not shown) that is remotely located from the hardware being controlled by the processor 222. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 222, transforms the general-purpose computer into a specific purpose computer (controller) that controls the chamber operation such that the processes are performed.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one implementation” of the present disclosure are not intended as limiting. Additional implementations may also incorporate the recited features.

Furthermore, the terms “substantial” or “substantially,” as well as the terms “approximate” or “approximately,” can be used interchangeably in some implementations, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific implementations described herein. Indeed, other various implementations of and modifications to the present disclosure, in addition to those described herein, will be apparent to those of ordinary skill in the art from the foregoing description and accompanying drawings. Thus, such other implementations and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a source/drain (S/D) epitaxial region in a front side of a substrate;
forming a back side epitaxial layer atop the S/D epitaxial region, wherein the back side epitaxial layer is formed within a contact via of a back side of the substrate;
amorphizing the back side epitaxial layer by delivering a pre-amorphization implant into the contact via;
implanting a dopant into the back side epitaxial layer after the back side epitaxial layer is amorphized; and
performing a thermal treatment to the back side epitaxial layer following the dopant implant, wherein the thermal treatment is performed at a temperature less than 650° C.

2. The method of claim 1, further comprising:
forming a silicide layer along a top surface of the back side epitaxial layer; and
depositing a metal fill over the silicide layer to form a back side contact.

3. The method of claim 1, wherein delivering the pre-amorphization implant into the contact via comprises delivering germanium ions or gallium ions into a top surface of the back side epitaxial layer, and wherein the germanium ions or the gallium ions are delivered while the substrate is at a temperature less than 0° C.

4. The method of claim 3, wherein the germanium ions or gallium ions are delivered while the substrate is at a temperature less than −50° C.

5. The method of claim 1, wherein implanting the dopant into the back side epitaxial layer comprises delivering a p-channel metal oxide semiconductor (PMOS) dopant into a top surface of the back side epitaxial layer.

6. The method of claim 5, wherein the PMOS dopant is boron or gallium.

7. The method of claim 1, wherein performing the thermal treatment to the back side epitaxial layer comprises performing a direct surface laser anneal.

8. The method of claim 1, further comprising forming an area of regrowth along a top surface of the back side epitaxial layer as a result of the thermal treatment.

9. A method of forming a back side contact, comprising:
forming a source/drain (S/D) epitaxial region in a front side of a substrate;
forming a back side epitaxial layer atop the S/D epitaxial region, wherein the back side epitaxial layer is formed within a contact via of a back side of the substrate;
amorphizing the back side epitaxial layer by delivering a pre-amorphization implant into a top surface of the back side epitaxial layer;
implanting a dopant into the back side epitaxial layer after the back side epitaxial layer is amorphized;
performing a thermal treatment to the back side epitaxial layer following the dopant implant, wherein the thermal treatment is performed at a temperature less than 650° C.; and
forming a back side contact within the contact via by siliciding the back side epitaxial layer and forming a metal fill within the contact via.

10. The method of claim 9, wherein delivering the pre-amorphization implant into the contact via comprises delivering germanium ions or gallium ions into the top surface of the back side epitaxial layer, and wherein the germanium ions or the gallium ions are delivered while the substrate is at a temperature less than 0° C.

11. The method of claim 10, wherein the germanium ions or gallium ions are delivered while the substrate is at a temperature less than −50° C.

12. The method of claim 9, wherein implanting the dopant into the back side epitaxial layer comprises delivering a p-channel metal oxide semiconductor (PMOS) dopant into the top surface of the back side epitaxial layer.

13. The method of claim 12, wherein the PMOS dopant is boron or gallium.

14. The method of claim 9, wherein performing the thermal treatment to the back side epitaxial layer comprises performing a direct surface laser anneal.

15. The method of claim 9, further comprising forming an area of regrowth along the top surface of the back side epitaxial layer as a result of the thermal treatment.

16. A method of forming a back side contact of a metal oxide semiconductor, the method comprising:
forming a source/drain (S/D) epitaxial region in a front side of a substrate;
forming a back side epitaxial layer atop the S/D epitaxial region, wherein the back side epitaxial layer is formed within a contact via of a back side of the substrate;
amorphizing the back side epitaxial layer by delivering a pre-amorphization implant into a top surface of the back side epitaxial layer, wherein the pre-amorphization implant is performed at a temperature less than 0° C.;
implanting a dopant into the back side epitaxial layer after the back side epitaxial layer is amorphized;
performing a thermal treatment to the back side epitaxial layer following the dopant implant, wherein the thermal treatment is performed at a temperature less than 650° C.; and
forming a back side contact within the contact via.

17. The method of claim 16, wherein delivering the pre-amorphization implant into the contact via comprises delivering germanium ions or gallium ions into the top surface of the back side epitaxial layer, and wherein the germanium ions or the gallium ions are delivered while the substrate is at a temperature less than −25° C.

18. The method of claim 16, wherein implanting the dopant into the back side epitaxial layer comprises delivering a p-channel metal oxide semiconductor (PMOS) dopant into the top surface of the back side epitaxial layer.

19. The method of claim 18, wherein the PMOS dopant is boron or gallium.

20. The method of claim 16, wherein performing the thermal treatment to the back side epitaxial layer comprises performing a direct surface laser anneal, and wherein an area of regrowth is formed along the top surface of the back side epitaxial layer as a result of the direct surface laser anneal.
